(19) United States
(12) Patent Application Publication
(10) Pub. No.: US 2026/0182359 A1
(43) Pub. Date: Jun. 25, 2026

(54) THERMAL CONTACTS FOR MIXED DOMAIN SEMICONDUCTOR DEVICES

(71) Applicant: Taiwan Semiconductor Manufacturing Company, Ltd., Hsinchu (TW)

(72) Inventors: Yu-Hao Chen, New Taipei City (TW); Chung-Ming Weng, Hsinchu City (TW); Hui Yu Lee, Hsinchu City (TW); Jui-Feng Kuan, Hsinchu City (TW); An-Jhih Su, Hsinchu City (TW)

(73) Assignee: Taiwan Semiconductor Manufacturing Company, Ltd., Hsinchu (TW)

(21) Appl. No.: 19/170,937

(22) Filed: Apr. 4, 2025

Related U.S. Application Data
(60) Provisional application No. 63/737,093, filed on Dec. 20, 2024.

(51) Int. Cl. H01L 23/532; H01L 21/768; H01L 23/373; H10D 86/00

(52) U.S. Cl. CPC H10W 20/48; H10D 86/201; H10W 20/081; H10W 40/254

(57) ABSTRACT

A semiconductor device is provided. The semiconductor device includes a silicon-photonic region thermally coupled with an electrical active region via a substrate, the electrical active region including a first transistor. A source/drain region of the first transistor is coupled with a thermal contact including a first material. The source/drain region of the first transistor is coupled with an electrical contact including a second material, different from the first material. The semiconductor device includes a first device terminal coupled with the electrical contact. The semiconductor device includes a second device terminal coupled with the thermal contact.

### CROSS-REFERENCE TO RELATED APPLICATIONS

This application claims the benefit of and priority to U.S. Provisional Ser. No. 63/737,093, filed Dec. 20, 2024, the entirety of which is herein incorporated by reference for all purposes.

### BACKGROUND

Semiconductor devices are used in a variety of electronic applications, such as personal computers, cell phones, digital cameras, and other electronic equipment. Semiconductor devices are fabricated by sequentially depositing insulating or dielectric layers, conductive layers, and semiconductor layers of material over a substrate, and patterning the various material layers using lithography to form circuit components and elements thereon. As the semiconductor industry has progressed into nanometer technology process nodes in pursuit of higher device density, a semiconductive substrate can host various circuit domains. According, the circuit domains can couple with one-another via the substrate.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a flow diagram for a method of semiconductor device fabrication, in accordance with some embodiments.

FIGS. 2, 3, 4, 5, 6, and 7 illustrate various views of an example semiconductor device during various fabrication stages according to the method of FIG. 1, in accordance with some embodiments.

FIGS. 8, 9, 10, 11, and 12 illustrate top views of example semiconductor devices during various fabrication stages according to the method of FIG. 1.

FIG. 13 illustrates a perspective view of an example finFET semiconductor device, in accordance with some embodiments.

FIG. 14 illustrates a perspective view of an example GAAFET semiconductor device, in accordance with some embodiments.

FIG. 15 illustrates a perspective view of an example nanosheet semiconductor device, in accordance with some embodiments.

FIG. 16 illustrates an example cross sectional view of another nanosheet transistor coupled with electrical and thermal contacts, in accordance with some embodiments.

FIG. 17 illustrates an example perspective view of the nanosheet transistor of FIG. 16, in accordance with some embodiments.

FIG. 18 illustrates an example cross sectional view of a fully depleted silicon-on-insulator device coupled with electrical and thermal contacts, in accordance with some embodiments.

FIG. 19 illustrates a flow diagram for a method of semiconductor device fabrication, in accordance with some embodiments.

FIGS. 20, 21, 22, and 23 illustrate various views of an example semiconductor device during various fabrication stages according to the method of FIG. 19, in accordance with some embodiments.

FIG. 24 illustrates an example semiconductor device having a carrier substrate from an active surface, in accordance with some embodiments.

FIG. 25 illustrates an example semiconductor device having an active surface thermally coupled with terminals on a front side, and a backside of the semiconductor device, in accordance with some embodiments.

FIG. 26 illustrates an example semiconductor device having an active surface thermally coupled with terminals on a front side, and a backside heat spreader of the semiconductor device, in accordance with some embodiments.

FIG. 27 illustrates an example semiconductor device having an active surface thermally coupled with terminals on a front side, and a backside heat sink of the semiconductor device, in accordance with some embodiments.

FIG. 28 illustrates an example semiconductor device including a first substrate having an active surface thermally coupled with a second substrate, and a backside terminal of the first substrate, in accordance with some embodiments.

FIG. 29 illustrates an example semiconductor device having an active surface thermally coupled with frontside and backside terminals, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. References to “or” may be construed as inclusive so that any terms described using “or” may indicate any of a single, more than one, and all of the described terms. References to at least one of a conjunctive list of terms may be construed as an inclusive OR to indicate any of a single, more than one, and all of the described terms. For example, a reference to “at least one of ‘A’ and ‘B’” can include only ‘A’, only ‘B’, as well as both ‘A’ and ‘B’. Such references used in conjunction with “comprising” or other open terminology can include additional items.

Generally, semiconductor device can include multiple domains, such as analog logic, digital logic, high speed serial, radio frequency (RF), or so forth. The circuits can be electrically or thermally isolated from on-another to avoid mutual interference therebetween. For example, a transistor, diode, or other component can couple with a guard ring via a metallization layer to offload a portion of heat. Such a coupling can include a thermal or electrical connections, such that any difference in potential between the component and the guard ring can induce a current, further contributing to device heating. Further, a silicon-on-insulator (SOI) device can include a buried oxide layer (BOX) below a channel, as may form a thermal barrier for the component, but the loss of the substrate as a heatsink can inhibit device performance, efficiency, or so forth.

Some domains, including photonic domains (e.g., silicon-photonic domains), can exhibit sensitivity to thermal changes. Accordingly, when photonic domains are included on a same substrate as an electrical domain, thermal management can strongly impact the operation of the photonic components. Such sensitivity may be particularly pronounced with regard to silicon substrates, but may be observed with other semiconductive substrates including germanium, silicon-germanium, or various III-V compounds.

According to the present disclosure, thermal contacts can be coupled with components of an electrical domain of a circuit (e.g., a source/drain region of a transistor). For example, the thermal contacts can include non-electrically conductive materials such as Aluminum Nitride (AlN), Aluminum Oxide (Al2O3), Silicon Nitride (Si3N4), or Diamond. The thermal contacts can thermally couple with device terminals (e.g., balls or bumps provided along with similar device terminals of electrical terminals), heatsinks, heat spreaders, or so forth. In some embodiments, these connections can be thermally coupled with a backside of a device, such as by thermal connections using a through-substrate via structure (TSV, which is sometimes referred to as a through-silicon via in the case of a silicon substrate). Such connections can further include electrically conductive materials. For example, a thermally conductive and electrically non-conductive contact can be formed between a source/drain region and various metallization layer materials (e.g., copper, gold, tungsten, aluminum, or so forth). Accordingly, the metallization layer materials can thermally couple the source/drain region with various terminals, heatsink, heat spreaders, or so forth, while remaining electrically separated by the thermal contacts. Such an approach can avoid sinking heat into a silicon or other substrate as may improve a performance of other domains, such as a silicon-photonic domain coupled with the same substrate.

Although described as coupled with electrical domain components, the thermal contacts can be coupled with components of another domain (e.g., a photonic domain). For example, some photonic domain components can generate significant heat, or may be insulated (e.g., with a BOX) such that the provision of the thermal contacts can improve circuit performance. Indeed, thermal contacts can be provided across various domains of a semiconductor device.

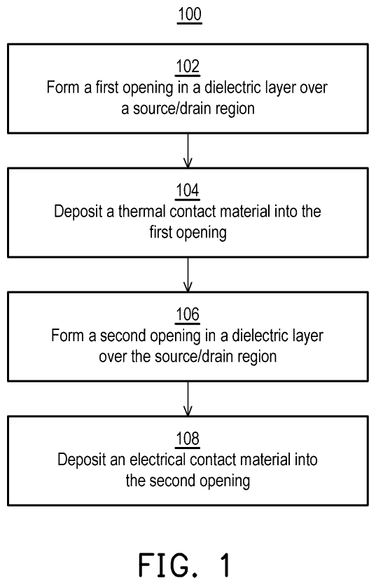

FIG. 1 illustrates a flow diagram for a method 100 of semiconductor device fabrication, in accordance with some embodiments. For example, at least some of the operations (or steps) of the method 100 may be used to form a semiconductor device including a silicon-photonic domain over a silicon substrate. It should be noted that the method 100 is merely an example, and is not intended to limit the present disclosure. Accordingly, it is understood that additional operations may be provided before, during, or after the method 100 of FIG. 1, and that some other operations may only be described briefly described herein.

In brief overview, the method 100 starts with operation 102 of forming a first opening on a dielectric layer (e.g., an interlayer dielectric, ILD), over a source/drain region. Next, the method 100 proceeds to operation 104 of depositing a thermal contact material into the first opening. Next, the method 100 proceeds to operation 106 of forming a second opening on a dielectric layer (e.g., a ILD formed over the thermal contact material). Next, the method 100 proceeds to operation 108 of depositing an electrical contact material into the second opening.

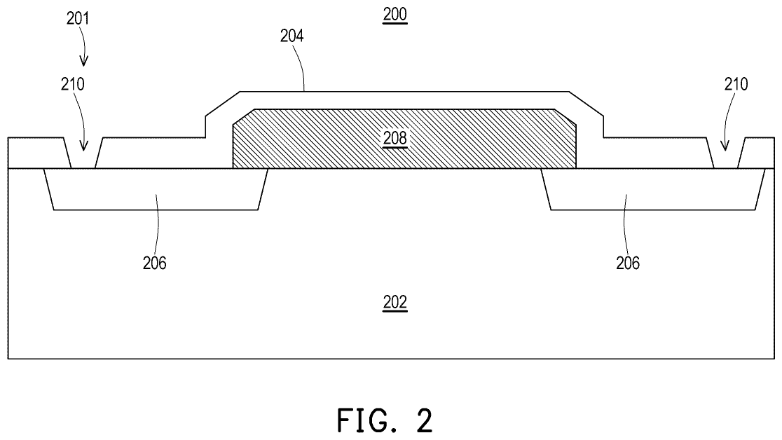

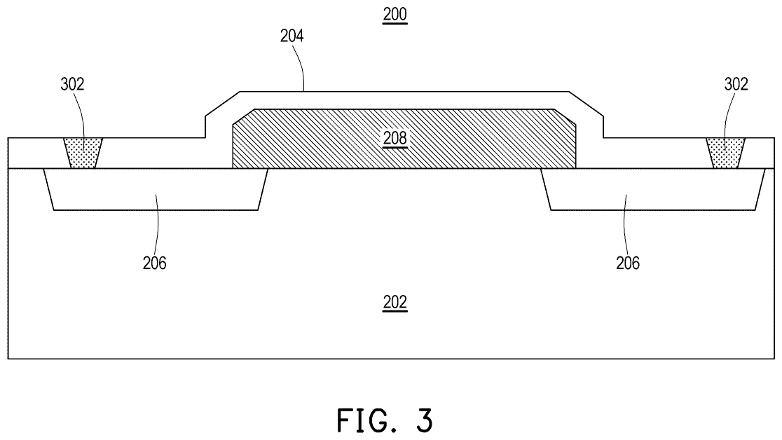

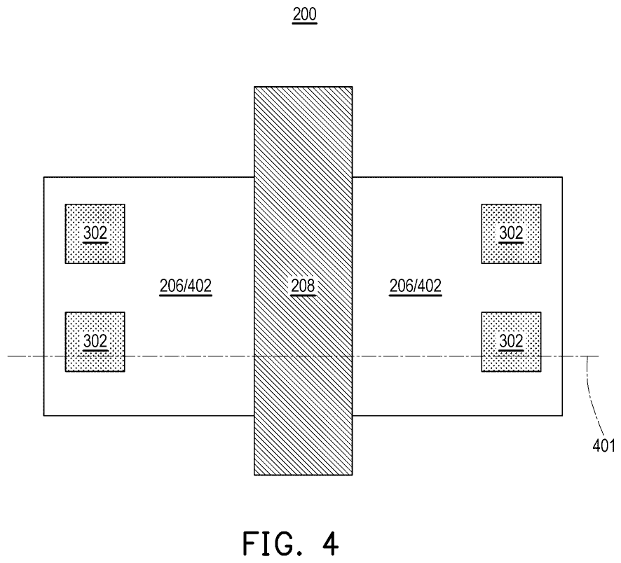

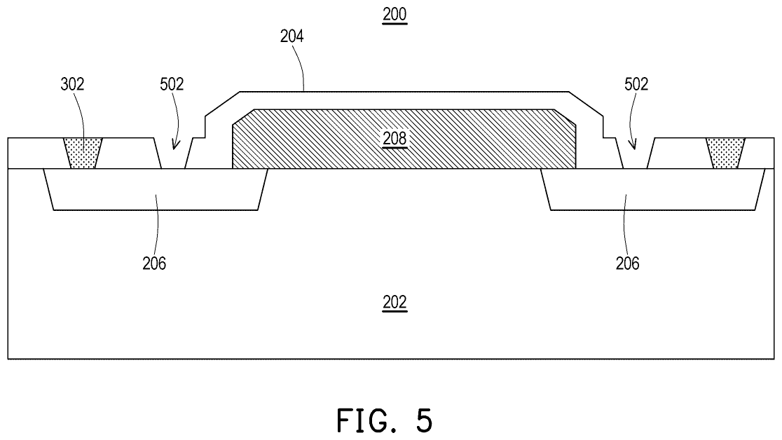

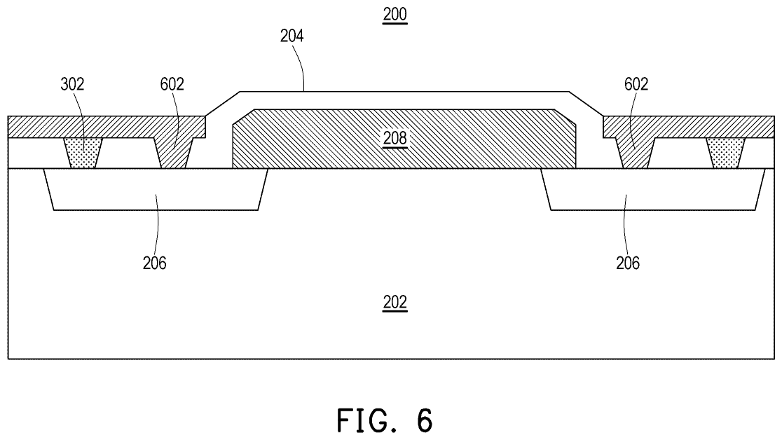

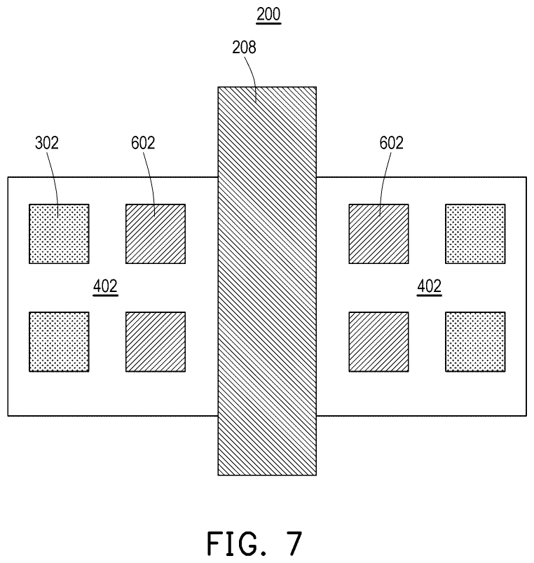

As mentioned above, FIGS. 2-7 each illustrate, in a top or cross-sectional view, a portion of a semiconductor device, at various fabrication stages of the method 100 of FIG. 1. More particularly, FIGS. 2-3 illustrate a formation of an opening and a formation of thermal contacts therein; FIG. 4 depicts a top view of the thermal contacts. FIGS. 5-6 depict a formation of second openings and a formation of electrical contacts therein. FIG. 7 depicts a top view of the electrical contacts laterally spaced from the thermal contacts. The depicted portion of the semiconductor device includes a transistor of an electrical region. A further portion of the semiconductor device can include another domain, such as a silicon-photonic domain. This other domain can be sensitive to temperature changes (e.g., a thermo-optic coefficient can impact operations of various photonic devices of the silicon-photonic domain).

Corresponding to operation 102 of FIG. 1, FIG. 2 illustrates a cross-sectional view of a semiconductor device 200 including a transistor formed on an active surface 201 of a substrate 202. More particularly, the transistor is provided as a planar transistor, although the present method 100, like other aspects of the present disclosure, can further be performed with finFETs, gate all around (GAA) transistors (e.g., nanosheet transistors), and further components configured to couple with an MD or other metallization layers. A dielectric layer 204 is formed over the source/drain regions 206 of the transistor. In some embodiments, as is depicted, the dielectric layer 204 can conformally cover a gate structure 208. First openings 210 can be patterned according to various techniques, including positive or negative photolithographic techniques to expose the source/drain regions 206. For example, a patterning process can be selective to the dielectric layer 204 relative to the source/drain regions 206, the patterning can be time-controlled, or an intermediate barrier layer can be provided between the source/drain regions 206 and the dielectric layer 204.

Corresponding to operation 104 of FIG. 1, FIG. 3 illustrates a cross-sectional view of a semiconductor device 200 including the transistor formed on an active surface 201 of a substrate 202. A thermal contact material is shown as deposited into the first openings 210 to form thermal contacts 302 thermally coupled with the source/drain regions 206. The thermal contact material is provided as non-electrically conductive (e.g., having an electrical resistance of greater than about one billion ohm-cm, such as greater than about 10 billion ohm-cm or greater). A thermal resistance can be provided as greater than about twenty watts per meter kelvin. The deposition can include various techniques, as may vary according to a selected material. For example, a physical vapor deposition process (sputtering) can be used to form contacts including Aluminum Nitride (AlN), Aluminum Oxide (Al2O3), or Silicon Nitride (Si3N4), among others. A chemical vapor deposition (CVD) process, such as low-pressure CVD, plasma-enhanced CVD, hot filament CVD, or metal-organic CVD can be used to form Aluminum Nitride, Aluminum Oxide, Silicon Nitride, or diamond contacts, among others. An atomic layer deposition (ALD) process may be used to form some thermal contact materials, such as Aluminum Oxide. Thermal contacts including further thermal contact materials can be formed using any of these processes, or further processes still.

With continued correspondence to operation 104 of FIG. 1, FIG. 4 illustrates a top view of a semiconductor device 200 including the thermal contacts 302. A cut plane 401 for the cross-sectional views of FIGS. 2-3 (and 5-6) is depicted to orient the present figure. In the provided view, the dielectric layer 204 is depicted transparently, to better depict an oxide diffusion region (OD) 402 including the source/drain regions 206. Various thermal contacts 302 are shown formed thereover the OD 402. A gate structure 208 (e.g., a poly gate) extends over the OD 402 to define the source/drain regions 206.

Corresponding to operation 106 of FIG. 1, FIG. 5 illustrates a cross-sectional view of a semiconductor device 200 including second openings 502. The second openings 502 can be formed using a same or similar technique as the first openings 210, or according to a further process. In some embodiments, the second openings 502 are formed subsequent to the deposition of the thermal contact material at operation 104. In some embodiments, the second openings 502 are formed simultaneously to the first openings, and the deposition of operation 104 is selective to the first openings 510 relative to the second openings 502.

Corresponding to operation 108 of FIG. 1, FIG. 6 illustrates a cross-sectional view of a semiconductor device 200 having an electrical contact material deposited into the second openings 502 to form electrical contacts 602 coupled with the source/drain regions 206. The electrical contact material is provided as electrically conductive (e.g., having a resistance of less than about one ohm-cm). The deposition can include various techniques, as may vary according to a selected material. For example, a such processes can include various electroplating, PVD, CVD, or ALD processes. The electrical contact material can include, for example, tungsten, copper, aluminum, gold, silver, or other conductors. The electrical contact material can be a same material, or otherwise configured to interface with various metallization layers. That is, the electrical contact material can form an MD.

With continued correspondence to operation 108 of FIG. 1, FIG. 7 illustrates a top view of a semiconductor device 200 including the thermal contacts 302 and electrical contacts 602. According to the depicted view, the thermal contacts 302 and the electrical contacts 602 are shown as identifiable in the top view. For example, the surface of the semiconductor device 200 can be planarized to the level of the ILD 204, such that the thermal contacts 302 and electrical contacts 602 extend to a same height. Subsequent layers can be formed over the thermal contacts 302 and electrical contacts 602. Even if these further layers are electrically conductive, the thermal contact 302 can insulate such layers from the source/drain region 206.

However, a portion of the electrical contact material covering the thermal contact 302 need not be removed. The electrical contact material can further exhibit thermal conductivity (in some embodiments, this thermal conductivity can exceed a thermal conductivity of the thermal contact material). Accordingly, the depicted electrical contact material can be patterned to remove the portion of the electrical contact material laterally connecting the thermal contacts 302 and the electrical contacts 602 (or the electrical contact material can be selectively deposited over the second opening 502 and the thermal contact 302). Such a process can provide a layer of the electrical contact material over the thermal contract 302, without electrically connecting the thermal contacts 302 and the electrical contacts 602. Accordingly, the thermal contact 302 can be coupled with further TSV, metallization layer, or other thermally and electrically conductive component to sink heat from the thermal contacts 302 without electrically connecting to the electrical contact 602.

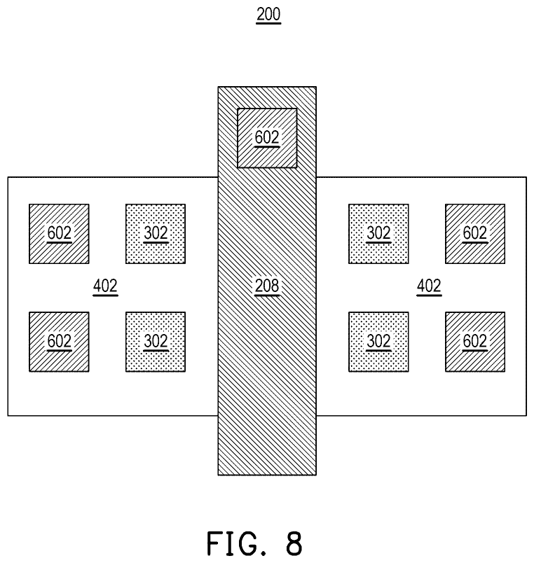

Referring generally to FIGS. 8-12, additional top views of example semiconductor devices 200 are depicted upon the fabrication stages according to the method of FIG. 1. The illustrative views are not intended to be exhaustive, but are provided to demonstrate advantages of various geometries of disposition for thermal contacts 302 and electrical contact 602. Aspects of the various depicted embodiments can be combined to generate further embodiments still. As for FIGS. 4 and 7, the ILD 204 is depicted transparently to better illustrate the disposition of the thermal contacts 302 and the electrical contact 602 relative to other features of the semiconductor device 200, including the OD 402, and the gate structure 208. Moreover, as for FIG. 7, the thermal contacts are depicted as visible, although they may be covered in a same material as the electrical contacts 602.

Referring to FIG. 8, thermal contacts 302 are depicted as laterally proximal to the gate structure 208, relative to the electrical contacts 602. Such a disposition can improve thermal transfer. For example, where a transistor includes a hotspot at a drain abutting the gate structure 208, the position of the thermal contact 302 proximal to the hotspot can improve thermal transfer, by reducing lateral thermal transfer through the OD 402 (which may, in turn, reduce a transference of heat into the substrate from the OD 402 and increase a thermal difference across the thermal contact 302). However, since the electrical contacts 602 are disposed further from the gate structure 208 than the thermal contacts 302, increased on-state resistance of the transistor may be observed (due to the length of the current path through the OD 402.) In some cases, such as a low-current transistor in a high-heat region, such a design can lead to overall reductions in temperature. In other cases, such as a power delivery network (PDN) transistor, the reduced on-state resistance associated with other layouts may better achieve reduced temperature (and reduced substrate heating). In some embodiments, thermal contacts 302 or electrical contacts 602 are provided asymmetrically on source/drain structures 206. For example, different quantities or positions of thermal contacts 302 or electrical contacts 602 can be provided between a source portion of an OD 402 and a drain portion of an OD 402, according to a thermal or electrical loading.

Further depicted is an electrical contact 602 landed on the gate structure 208. In some embodiments, thermal contacts 302 may also be landed on the gate structure 208, to further sink heat from the gate structure, or a semiconductor channel in contact with the gate structure 208.

For simplicity of the figures which, as indicated above, are not provided to scale, the thermal contacts 302 and electrical contacts 602 are shown as inverted between FIG. 7 and FIG. 8. However, various further adjustments can be provided. For example, thermal contacts 302 can be provided as larger or smaller than the electrical contacts 602. Moreover, certain design rule checks (DRCs) for electrical contacts 602 may not be applied to the thermal contacts 302. The thermal contacts 302 can be disposed in electrical keep-out areas, such as approaching or over an OD boundary, approaching or abutting the gate structure 208, or so forth. For example, a distance from a thermal contact 302 to an OD boundary, gate, electrical contact 602, other thermal contact 302, or other feature of the semiconductor device 200 can be less than a minimum distance for an electrical contact 602.

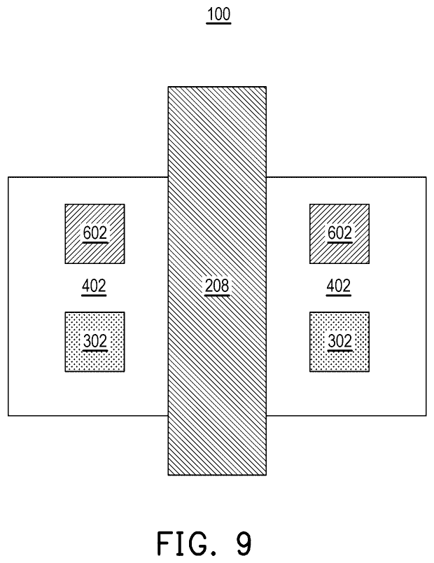

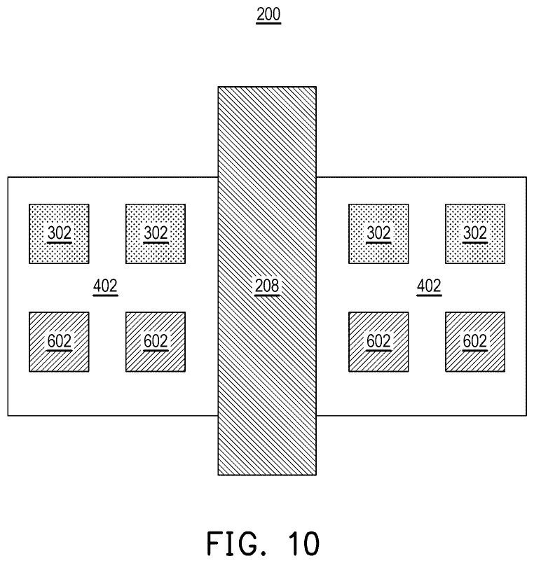

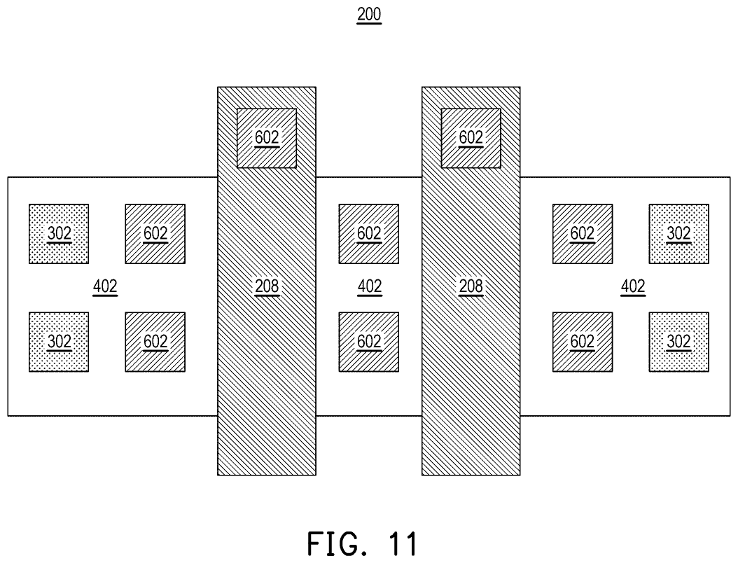

Referring to FIG. 9, a single thermal contact 302 and a single electrical contact 602 are depicted as equidistant from the gate structure 208. Referring to FIG. 10, a pair of thermal contacts 302 and a pair of electrical contacts 602 are depicted as equidistant from the gate structure 208. Referring to FIG. 11, an abutment including a dual gate structure (208A, 208B) is provided. Such a structure can provide increased surface area for contacts, such that an inclusion of thermal contacts 302 (e.g., four thermal contacts 302) need not reduce a number of electrical contacts 602.

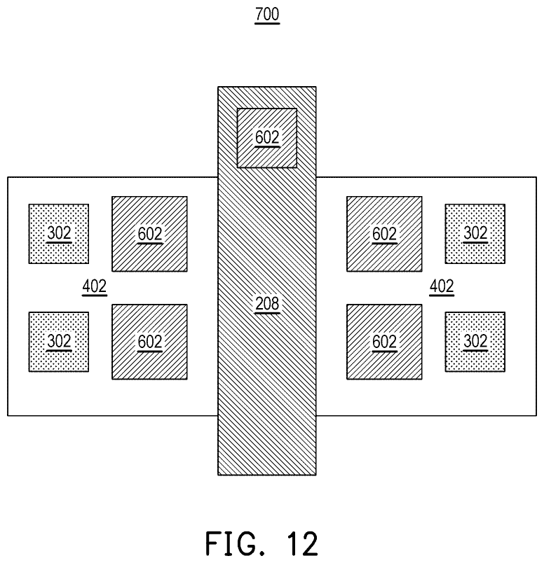

Referring to FIG. 12, an example of differently, sized thermal contacts 302 and electrical contacts 602 is provided. In some cases, the larger size of the electrical contacts 602 could complicate or preclude placement of further electrical contacts 602 (e.g., according to a minimum spacing requirement). For example, the OD 402 can be sized for four electrical contacts 602 at minimum spacing and offsets. However, according to a relaxed DRC applied to thermal contacts 302, electrical contacts can be formed laterally spaced from a delimiting distance (e.g., a boundary of an OD 402 for the source/drain region 206, a gate structure 208, or another electrical contact 602) by an offset distance according to a design rule check (DRC) distance. Thermal contacts 302 can be laterally formed according to a position violative of the DRC distance. In some cases, the violative position can include a negative offset (e.g., the thermal contact may only partially lateral overlap with the OD 402). In the illustrated example, the thermal contacts 302 are depicted as having a smaller lateral footprint in contact with the OD 402 than the electrical contacts 602. However, in further examples, thermal contacts 302 may be provided as having larger lateral footprint in contact with the OD 402 than the electrical contacts 602.

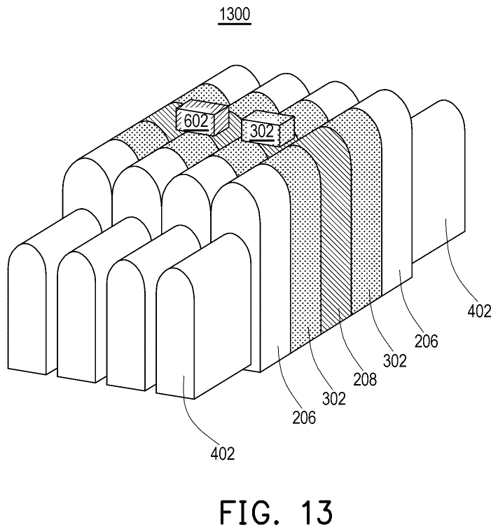

Referring generally to FIGS. 13-17, additional transistor types are provided to illustrate various further contemplated thermal contact 302 geometries. These illustrative examples should not be construed as limiting. Thermal contacts 302 can be provided with various further transistor types, as well as other passive or active components, according to the present disclosure.

FIG. 13 depicts a finFET transistor 1300 having a heavily doped source/drain region 206 abutting the OD 402 and in thermally contacting a thermal contact 302. An additional thermal contact 302 and electrical contact 602 are depicted as coupled with a gate structure 208. Although not depicted, the source/drain regions 206 can couple with further electrical contacts 602 as may be interconnected to form various circuits of an active surface 201.

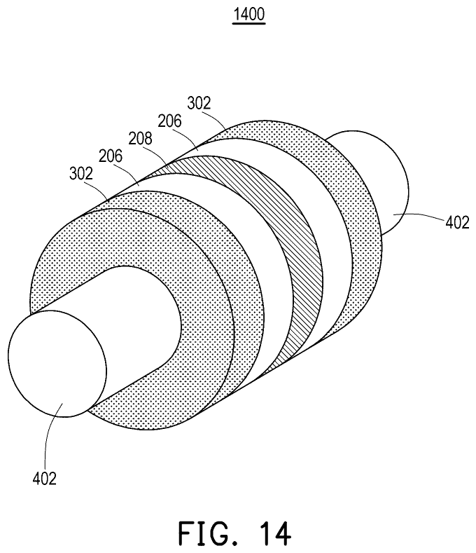

FIG. 14 depicts a GAAFET transistor 1400 having thermal contacts 302 in thermal communication with an OD 402 and source/drain regions 206 electrically coupled with a gate structure 208. Although not depicted, the source/drain regions 206, as well as the gate structure 208 can couple with further thermal contacts 302, as well as electrical contacts 602 to interconnect an active surface 201 of a semiconductor device to form circuits.

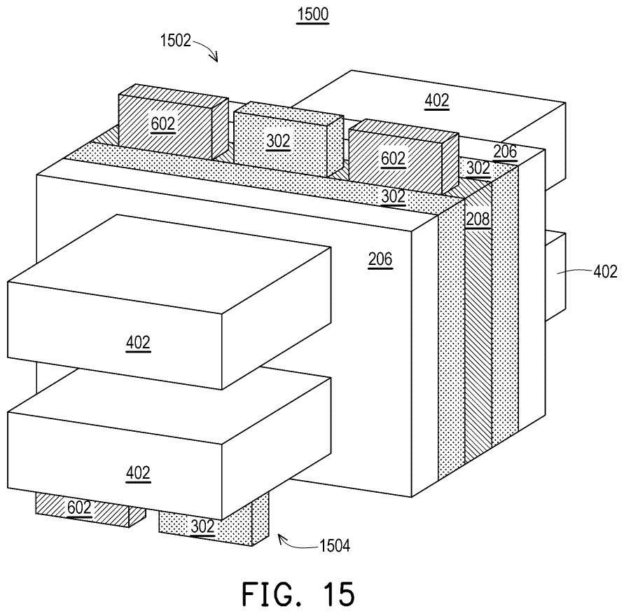

FIG. 15 depicts a nanosheet transistor having a gate structure 208 coupled with thermal contacts 302 and electrical contacts 602 on both of a frontside 1502 and backside 1504 of a semiconductor device 200. The gate structure 208 is electrically coupled with source/drain regions 206 at opposite ends of a semiconductor channel. The source/drain regions 206 (and the gate structure 208) are thermally coupled with a nanosheet thermal contact 302, and other portions of an OD 402.

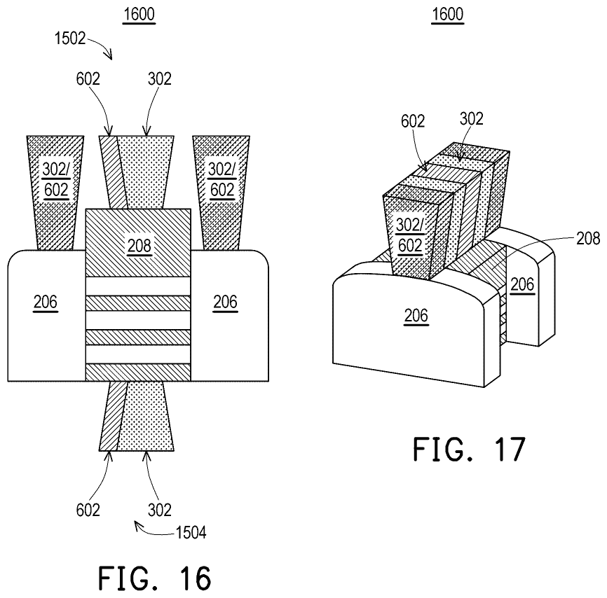

FIG. 16 depicts a cross sectional view of another nanosheet transistor 1600 having a gate structure 208 coupled with thermal contacts 302 and electrical contacts 602 on both of a frontside 1502 and backside 1504 of a semiconductor device 200. FIG. 17 depicts a perspective view of the nanosheet transistor 1600 of FIG. 17, from which the relative positions of the thermal contacts 302 and electrical contacts 602 can be observed. Further contacts are depicted as coupled with the source/drain regions 206, as may include any combination of thermal contacts 302 and electrical contacts 602.

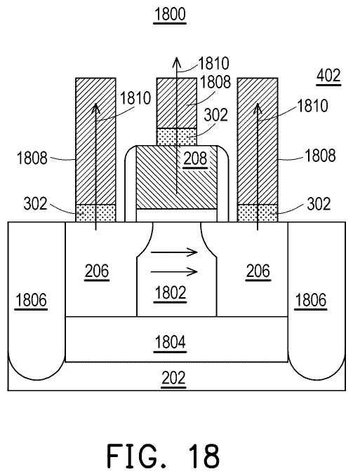

FIG. 18 illustrates an example cross sectional view of a fully depleted SOI device 1800 coupled with thermal contacts 302, in accordance with some embodiments. An electrical conduction channel 1802 is gated by the gate structure 208 to control an electrical connection between the source/drain regions 206. For example, the gate structure 208 can be connected to a gate electrode along a different cut plane than is depicted. Similarly, the source/drain regions 206 can coupled with electrical contacts 602 in another cut plane. The BOX region 1804 and STI regions 1806 can insulate a substrate 202 (e.g., bulk silicon of a silicon substrate 202) from heat generated by the SOI device 1800. However, as the heat accumulates, the insulation can become less effective, and, in any case, increased temperatures can impact operation of the SOI device 1800. Accordingly, sinking heat from the SOI device 1800 may be desired.

Thermal contacts 302 are provided in thermal communication with the gate structure 208, as well as source/drain regions 206 at a first end of the thermal contacts 302. The thermal contacts 302 are coupled with further thermally conductive via structures 1808 at a second end to form thermal flow paths 1810 away from the fully depleted SOI device 1800. The conductive via structures 1808 can be formed from a same material, process step, and so on, as electrical contacts or metallization layers as may reduce manufacturing complexity. Accordingly, the conductive via structures 1808 can be both thermally and electrically conductive, such that the resistance of the thermal contact 302 electrically separates the source/drain regions 206 from the conductive via structures 1808. The particular dimensions of the thermal contact 302 can vary according to an ILD 204, operating voltage, and other features of the semiconductor device 200. For example, for some devices, a minimum distance of about 7 nanometers can be provide sufficient electrical isolation.

Although depicted as a fully depleted SOI device, the transistor can be substituted for other devices, such as a partially depleted SOI device, bulk device, or so forth. In each case, the provision of the thermal flow paths 1810 can reduce device-self heating as well as heating of a silicon or other substrate 202. Reducing substrate heating can improve the operation of other domains coupled with the substrate, such as a any silicon-photonics devices of a same semiconductor device 200.

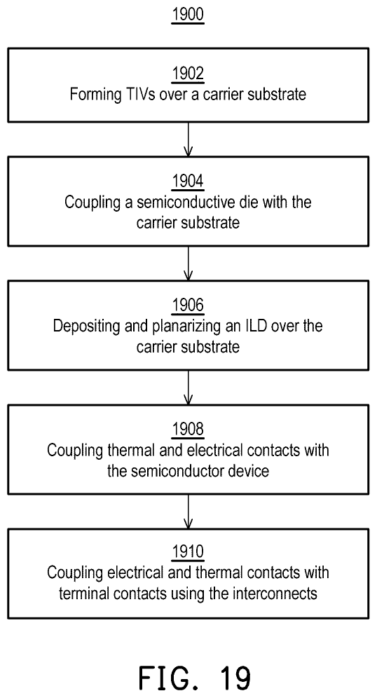

FIG. 19 illustrates a flow diagram for a method 1900 of semiconductor device 200 fabrication, in accordance with some embodiments. For example, at least some of the operations (or steps) of the method 1900 may be used to form a semiconductor device 200 including a silicon-photonic domain over a silicon substrate 202. It should be noted that the method 1900 is merely an example, and is not intended to limit the present disclosure. Accordingly, it is understood that additional operations may be provided before, during, and after the method 1900 of FIG. 19, and that some other operations may only be described briefly described herein.

In brief overview, the method 1900 starts with operation 1902 of forming through interlayer vias (TIVs) over a carrier substrate. Next, the method 1900 proceeds to operation 1904 of coupling a semiconductive die with the carrier substrate. Next, the method 1900 proceeds to operation 1906 of depositing and planarizing an ILD over the carrier substrate. Next, the method 1900 proceeds to operation 1908 of coupling thermal and electrical contacts with the semiconductor device. Next, the method 1900 proceeds to operation 1910 of forming interconnects (e.g., redistribution layers, RDL) over the semiconductor device. Next, the method 1900 proceeds to operation 1912 of coupling electrical and thermal contacts with terminal contacts using the interconnects.

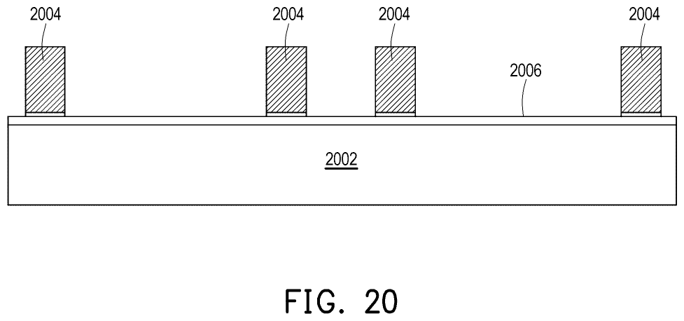

Corresponding to operation 1902 of FIG. 19, FIG. 20 illustrates a cross-sectional view of a semiconductor device 200 including a carrier substrate 2002 having TIVs 2004 formed thereover. The carrier substrate 2002 can include, for example, various glasses, silicon, sapphire, silicon carbide, or other carrier substrates. The TIVs 2004 can be formed according to various techniques including forming a dielectric layer, patterning openings in the dielectric layer (e.g., according to a deep reactive ion etch, mechanical or laser drilling, lithographic patterning, barrier and seed layer deposition and electroplating, among others). The TIVs 2004 can be formed directly over the carrier substrate or, as depicted, an intermediate layer, such as an adhesive layer 2006. The adhesive layer 2006 can be configured to de-bond according to an introduction of heat, ultraviolet light, solvents, mechanical forces, or other debonding mechanisms.

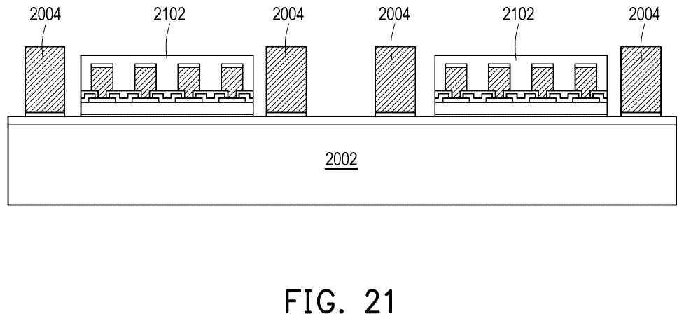

Corresponding to operation 1904 of FIG. 19, FIG. 21 illustrates a cross-sectional view of a semiconductor device 200 including the carrier substrate 2002 with multiple semiconductive dies 2102 coupled with a same surface as the TIVs 2004. The semiconductive dies 2102 can (individually or collectively) include various domains, such as an electrical domain and a silicon-photonics domain. When included on a same semiconductor die 2102, the domains can thermally couple through a substrate 202 of the die. When included on different dies, the domains can thermally couple through a molding dielectric of operation 1906, henceforth. As is depicted, the TIVs 2004 can protrude somewhat above the semiconductive dies 2102 prior to a planarization of operation 1906. Accordingly, exposing the upper surface of the semiconductive dies 2102 via the planarization operation will also expose the TIVs 2004.

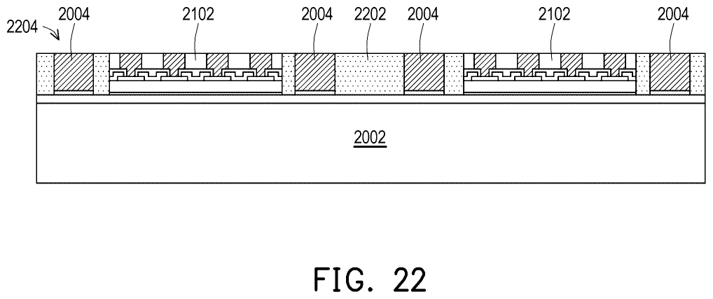

Corresponding to operation 1906 of FIG. 19, FIG. 22 illustrates a cross-sectional view of a semiconductor device 200 including a dielectric layer of a dielectric fill 2202. The dielectric fill 2202 (sometimes referred to as a mold compound or molded dielectric) can include epoxy-based materials configured to thermally and mechanically couple various portions of the semiconductor device 200. The dielectric layer can be formed by pouring, spin coating, compression molding, or other techniques. Subsequent to a deposition suboperation, the dielectric layer can be planarized according to a selected material. For example, a planarization suboperation can be performed using chemical mechanical grinding/polishing (CMP/G), mechanical grinding, or reactive ion etching according to a selected dielectric fill 2202. The planarization can leave a smooth surface, and further expose an upper surface of the semiconductor device 200 including an exposed surface of the semiconductive die 2102 and a first end 2204 of the TIV 2004 (the upper surface), laterally separated by the dielectric fill 2202. That is, a portion of the TIV 2004 extending above an upper surface of the semiconductor die 2102 can be removed as a part of the planarization suboperation.

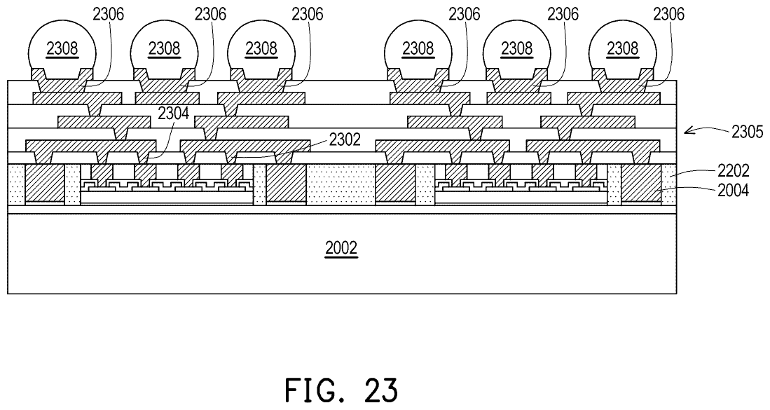

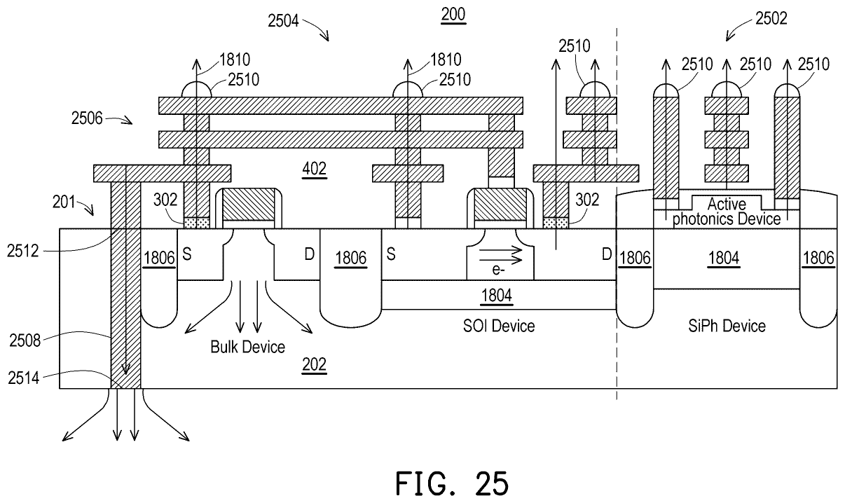

Corresponding to operations 1908 and 1910 of FIG. 19, FIG. 23 illustrates a cross-sectional view of a semiconductor device 200 including thermal contacts 302 and electrical contacts 602 coupled with an external feature of the semiconductor device 200. An external feature can include a pin, ball, bump, heat spreader, heatsink, wafer surface, or other component configured to thermally or electrically couple with an environment external to the semiconductor device 200. Some illustrative examples of external features are provided henceforth, with regard to FIGS. 25-29. The thermal contacts 302 and electrical contacts 602 can refer to contacts internal to the one or more semiconductor dies 2102 of the semiconductor devices 200 (e.g., as depicted in FIG. 6). The thermal contacts 302 and electrical contacts 602 can refer to contacts external to the one or more semiconductor dies 2102, such as contacts of a redistribution layer (RDL) or other interconnect layer. For example, a pad metal layer coupled with an RDL can be or include one or more RDL thermal contact 2302 in addition to any RDL electrical contacts 2304. The various pad metal layers and RDL layers can be formed by single or double damascene processes. Further depicted is an example of an under ball/bump metallization structure (UBM) 2306 coupled with a terminal contact of a ball/bump 2308. The ball, bump, or another external feature of the semiconductor device 200 can couple with the thermal contact 302 or electrical contact 602 through the RDL or another interconnect layer 2305.

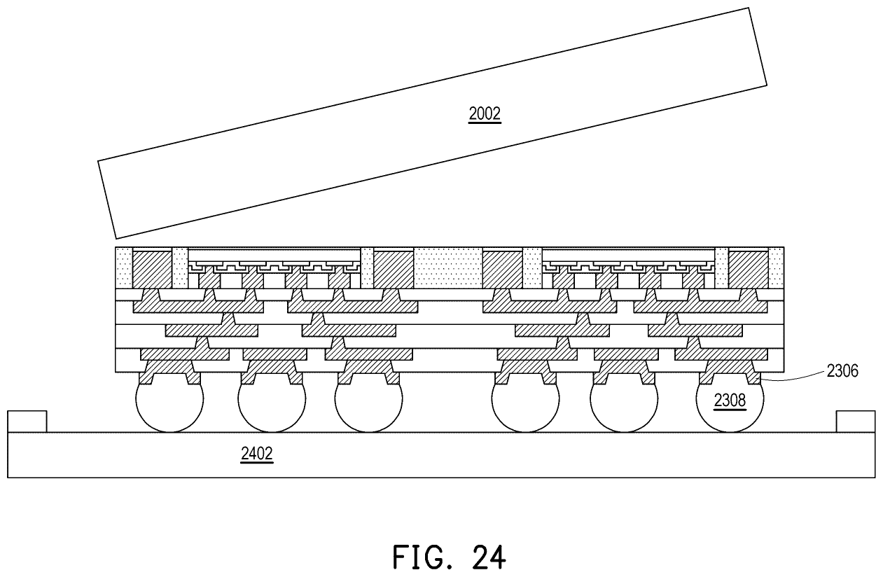

Referring now to FIG. 24, the carrier substrate 2002 is shown as removed from the semiconductor device 200. The removal can be performed according to various debonding mechanisms, as indicated with regard to operation 1902. The ball/bump 2308, other terminal contact (e.g., pin, lead, pillar, or pad), or other external feature (e.g., heatsink, heat spreader, wafer surface) can be configured to thermally couple with an environment external to the depicted semiconductor device 200. For example, the terminal contact can be exposed to air for convective transfer, or, more commonly, coupled with a printed circuit board assembly (PCBA), interposer, or other further substrate 2402 suitable for further integration. Accordingly, the external features can regulate (e.g., sink or source) heat of the semiconductor device 200 to maintain a window of operation for one or more domains thereof (e.g., a silicon-photonics domain). In some embodiments, the method 1900 can include coupling a second semiconductive die including a second photonics region or a second electronic region to a second end of the TIV 2004, opposite from the first end.

Referring generally to FIGS. 25-29, semiconductor devices 200 are depicted as having a silicon-photonic region 2502 (also referred to as a silicon-photonic domain, without limiting effect) laterally spaced from an electrical active region 2504 (also referred to as an electrical domain, without limiting effect). The silicon-photonic region 2502 can include optical modulators, photodetectors, waveguides, micro-ring resonators, couplers, splitters, and other devices as may be optically or electrically coupled with one another to form optical integrated circuits (OIC). Although depicted with a limited number of devices to aid with the clarity of the figures, a silicon-photonic region 2502 can include several (e.g., millions or billions) of components. Likewise, although depicted as a pair of transistors, to aid with the clarity of the figures, an electrical active region 2504 can include several (e.g., millions or billions) of transistors, diodes, capacitors, resistors, or other components.

The silicon-photonic regions 2502 are thermally coupled with the electrical active region 2504 via a substrate 202. Electrical contacts 602 are provided to electrically interconnect various components to form circuits (e.g., gate structures 208, source/drains regions 206, or so forth). Thermal contacts 302 can interconnect various components to sink heat from the semiconductor device 200 to external features, as may avoid impeding thermally sensitive circuits of the silicon-photonic region 2502. The electrically active region 2504 can include bulk transistors thermally coupled with the substrate 202 without an intervening BOX 1804. One or more thermal contacts 302 including a first material (e.g., Aluminum Nitride, Aluminum Oxide, Silicon Nitride, or diamond, or another thermally conductive, electrically resistive material) can provide a thermal flow path 1810 away from the transistor, reducing a portion of heat sunk by the substrate 202 (and transferred to the silicon-photonics region 2504). For example, the thermal flow path 1810 can include an external feature of the semiconductor device such as a device terminal. Any number of thermal or electrical contacts can be provided for each device terminal (e.g., source/drain region 206 or a gate structure 208 of a transistor). For example, the electrical region 2504 can include another transistor, having a source/drain region 206 coupled with a second thermal contact 302 including the first material and a second electrical contact including the second material.

The electrically active region 2504 can include SOI transistors thermally coupled with the substrate 202 with an intervening BOX 1804. The SOI transistor can be provided as fully depleted or partially depleted. One or more thermal contacts 302 including the first material can couple with the same or different device terminal. Thermal contacts can couple with external features according to a one-to-one mapping, n-to-one mapping, one-to-n mapping, or n-to-n mapping. For example, several thermal contacts 302 can thermally couple with a same device terminal. The various devices of the silicon-photonics region 2502 can include thermal contacts 302 to provide thermal sinking, similar to the described electrical contacts 602. Moreover, the silicon-photonics region 2502 can include spacings, guard rings, BOX 1804 or other features to thermally insulate from the substrate 202. For example, a BOX 1804 of the silicon-photonics region 2502 can be provided as thicker than a BOX 1804 of the electrically active region 2504, as may improve thermal insulation for a lower power circuit. The depicted transistors are depicted as laterally separated by STI regions 1806.

Referring to FIG. 25 in further detail, an example semiconductor device 200 having an active surface 201 thermally coupled with device terminals 2510 on a front side, and a backside of the semiconductor device 200 is provided in accordance with some embodiments. As depicted, the substrate includes a TSV 2508 formed through the substrate 202 the semiconductor device 200. A first end 2512 of the TSV 2508 is coupled with a plurality of metallization layers 2506 formed over a front surface of the semiconductor device (and thermally coupled with the thermal contact). The metallization layers 2506 can include a same material as the electrical contact 602, or can include a third material coupling the first device terminal with the electrical contact and the second device terminal with the thermal contact 302.

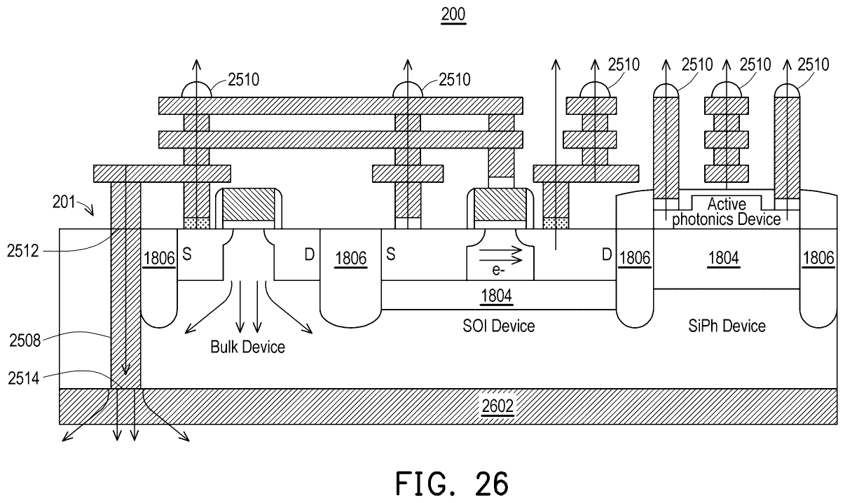

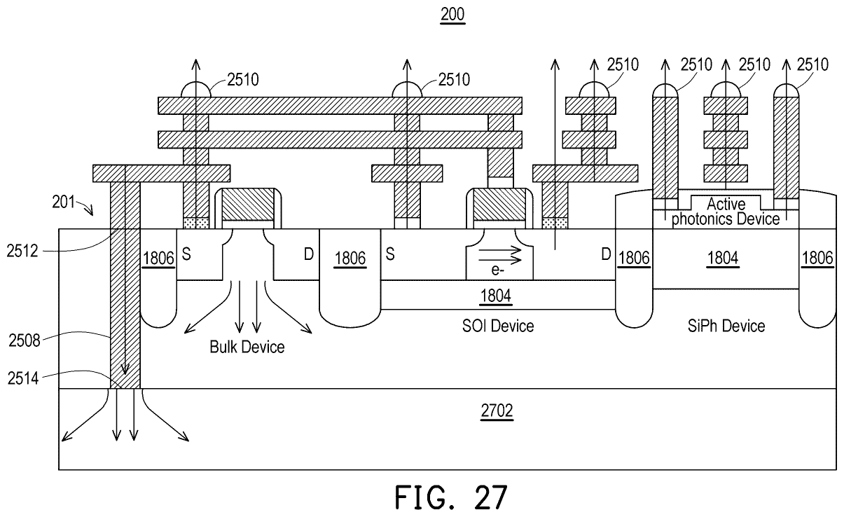

A second end 2514 of the TSV 2508 is coupled with a backside of the semiconductor device 200, opposite from the active surface 201. The second end 2514 of the TSV 2508 can provide a convective thermal flow path 1810 to the back side of the semiconductor device 200, or as depicted in FIGS. 26-27, henceforth, can couple with another external feature of the semiconductor device 200.

Referring to FIG. 26, an example semiconductor device 200 having an active surface 201 thermally coupled with terminals 2510 on a front side, and a backside heat spreader 2602 of the semiconductor device 200 is provided in accordance with some embodiments. That is, the second end 2514 of the TSV 2508 can provide a conductive thermal flow path 1810 through the heat spreader 2602 and on to further materials interfacing therewith.

Referring to FIG. 27, an example semiconductor device 200 having an active surface 201 thermally coupled with terminals 2510 on a front side, and a backside heat sink 2702 of the semiconductor device 200 is provided in accordance with some embodiments. That is, the second end 2514 of the TSV 2508 can provide a conductive thermal flow path 1810 through the heat sink 2702 which can, in turn, provide a convective thermal flow path 1810 to a fluid in contact therewith.

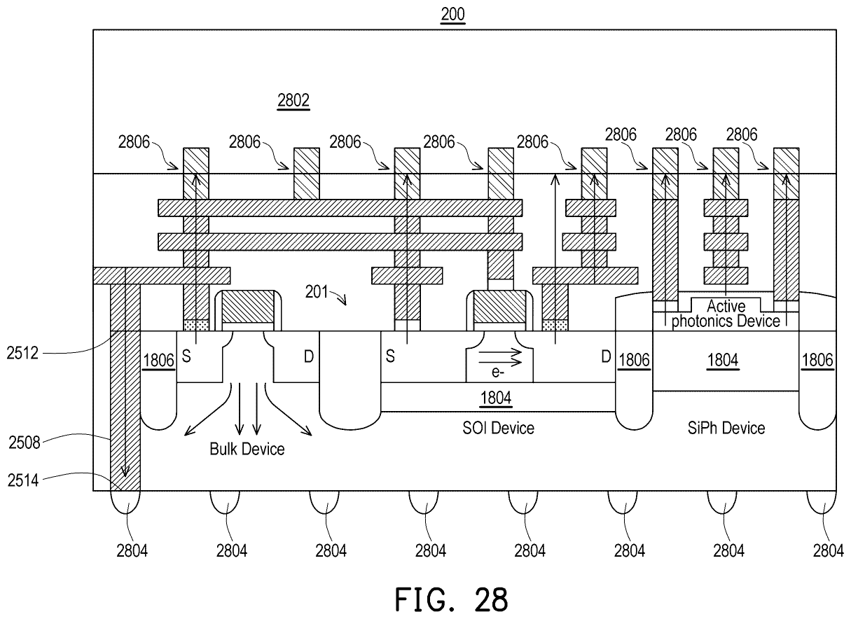

Referring to FIG. 28, an example semiconductor device 200 having an active surface 201 of a first substrate 202 thermally coupled with a second substrate 2802, and a backside terminal 2804 of the first substrate 202 is provided in accordance with some embodiments. The backside terminal 2804 can connect to further interposers, PCBA, semiconductive dies, or other features. The backside can provide a substantial portion (e.g., a majority) of thermal sinking from the first substrate 202. For example, the frontside of the first substrate 202 can be bonded (e.g., according to a hybrid dielectric and copper-pillar 2806 bond), as may inhibit thermal egress, or further contribute to a thermal load of the first substrate 202.

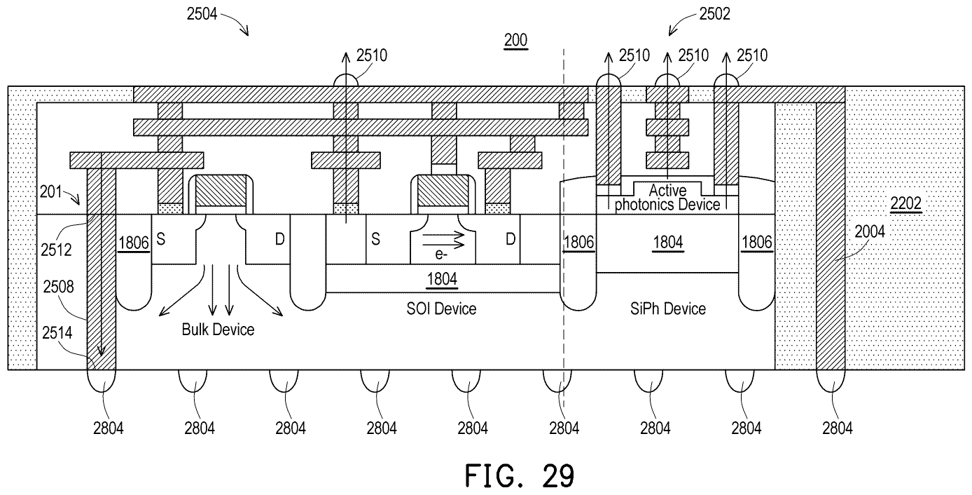

Referring to FIG. 29, an example semiconductor device 200 having an active surface 201 thermally coupled with frontside terminals 2510 and backside terminals 2804 is provided in accordance with some embodiments. Various via structures include a TSV 2508 extending through the substrate 202 and another TIV 2004 extending through a dielectric fill 2202 laterally offset from the substrate. The separate TIV 2004 can couple separately with the silicon-photonic region 2502 and the electrical region 2504, as may reduce thermal transfer between the silicon-photonic region 2502 and the electrical region 2504. For example, by extending the TIV 2004 through the dielectric fill 2202, thermal transfer from the substrate 202 can be avoided, and even relatively low heats can be sunk to the depicted frontside terminals 2510 and backside terminals 2804, or any other external features, such as the heat spreader, heatsinks, or further components depicted herein or known in the art. Indeed, as indicated above, various aspects of FIGS. 25-29, (or other aspects of the present disclosure) can be substituted, modified, omitted, or added.

In one aspect of the present disclosure, a semiconductor device is provided. The semiconductor device includes a silicon-photonic region thermally coupled with an electrical active region via a substrate, the electrical active region including a first transistor. A source/drain region of the first transistor is coupled with a thermal contact including a first material. The source/drain region of the first transistor is coupled with an electrical contact including a second material, different from the first material. The semiconductor device includes a first device terminal coupled with the electrical contact. The semiconductor device includes a second device terminal coupled with the thermal contact.

In another aspect of the present disclosure, a semiconductor device is provided. The semiconductor device includes a dielectric layer over a source/drain region. The semiconductor device includes various metallization layers coupled with a terminal contact of the semiconductor device. The semiconductor device includes a thermal contact thermally coupled with the source/drain region at a first end and a conductive via structure at a second end, the second end coupled with the terminal contact via the various metallization layers. The semiconductor device includes an electrical contact including a different material than the thermal contact. The electrical contact is laterally offset from the thermal contact. The electrical contact couples the source/drain region to one or more of the various metallization layers.

In another aspect of the present disclosure, a method of fabricating a semiconductor device is provided. The method includes patterning an interlayer dielectric (ILD) over a source/drain region to form a first opening. The method includes forming a thermal contact material into the first opening to form a thermal contact coupled with the source/drain region. The method includes patterning the ILD over the source/drain region to form a second opening laterally spaced from the thermal contact. The method includes forming an electrical contact material into the second opening to form an electrical contact coupled with the source/drain region. The method includes coupling, via a plurality of metallization layers, the thermal contact with a terminal contact of the semiconductor device.

In another aspect of the present disclosure, a method of fabricating a semiconductor device is provided. The method includes forming a plurality of through interlayer via (TIV) over a carrier substrate. The method includes coupling a semiconductive die having a silicon-photonic region and an electrical active region. The method includes forming and planarizing a dielectric fill over the carrier substrate to expose an upper surface of the semiconductor device including an exposed surface of the semiconductive die and a first end of the TIV, laterally separated by the dielectric fill. The method includes coupling a thermal contact of a first material with a first external feature of the semiconductor device and an electrical contact of a second material with a second external feature.

As used herein, the terms “about” and “approximately” generally indicates the value of a given quantity that can vary based on a particular technology node associated with the subject semiconductor device 200. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a silicon-photonic region thermally coupled with an electrical active region via a substrate, the electrical active region comprising a first transistor, wherein a source/drain region of the first transistor is coupled with:
a thermal contact comprising a first material; and
an electrical contact comprising a second material, different from the first material;
a first device terminal coupled with the electrical contact; and
a second device terminal coupled with the thermal contact.

2. The semiconductor device of claim 1, wherein the electrical active region comprises a second transistor, wherein a source/drain region of the second transistor is coupled with a second thermal contact comprising the first material and a second electrical contact comprising the second material.

3. The semiconductor device of claim 1, wherein the substrate is a silicon substrate.

4. The semiconductor device of claim 3, wherein the substrate comprises a buried oxide layer (BOX) between:
the electrical active region and bulk silicon of the substrate; or
the silicon-photonic region and bulk silicon of the substrate.

5. The semiconductor device of claim 4, wherein the BOX is a BOX of a fully depleted SOI device.

6. The semiconductor device of claim 4, wherein the BOX is a BOX of a partially depleted SOI device.

7. The semiconductor device of claim 1, further comprising:
a plurality of metallization layers of a third material coupling the first device terminal with the electrical contact and the second device terminal with the thermal contact.

8. The semiconductor device of claim 1, wherein:
the first material exhibits a thermal conductivity of greater than about twenty watts per meter kelvin and an electrical resistivity of greater than about 10 billion ohm-cm.

9. The semiconductor device of claim 6, wherein the first material is selected from the group consisting of Aluminum Nitride (AlN), Aluminum Oxide (Al2O3), Silicon Nitride (Si3N4), or Diamond.

10. The semiconductor device of claim 1, wherein:
the electrical contact is laterally bounded within an oxide diffusion region (OD) and laterally spaced from a boundary of the OD by an offset distance; and
the thermal contact is laterally spaced from the boundary of the OD by distance less than the offset distance.

11. A semiconductor device, comprising:
a dielectric layer over a source/drain region;
a plurality of metallization layers coupled with a terminal contact of the semiconductor device;
a thermal contact thermally coupled with the source/drain region at a first end and a conductive via structure at a second end, the second end coupled with the terminal contact via the plurality of metallization layers; and
an electrical contact comprising a different material than the thermal contact, laterally offset from the thermal contact, electrically coupling the source/drain region to one or more of the plurality of metallization layers.

12. The semiconductor device of claim 11, further comprising a through-substrate via structure (TSV) having a first end electrically coupled with the second end of the thermal contact via one or more of the plurality of metallization layers, and a second end coupled with an external feature on a back side of the semiconductor device, opposite from an active surface comprising the source/drain region.

13. The semiconductor device of claim 11, wherein:
the electrical contact is laterally spaced from a boundary of an OD for the source/drain region by an offset distance according to a design rule check (DRC) distance; and
the thermal contact is closer to the boundary than the DRC distance.

14. The semiconductor device of claim 11, wherein:
the material of the thermal contact exhibits a thermal conductivity of greater than about twenty watts per meter kelvin and an electrical resistivity of greater than about 10 billion ohm-cm.

15. The semiconductor device of claim 14, wherein the material of the thermal contact is selected from the group consisting of Aluminum Nitride (AlN), Aluminum Oxide (Al2O3), Silicon Nitride (Si3N4), or diamond.

16. A method of fabricating a semiconductor device, comprising:
forming a plurality of through interlayer via (TIV) over a carrier substrate;
coupling a semiconductive die having a silicon-photonic region and an electrical active region;
forming and planarizing a dielectric fill over the carrier substrate to expose an upper surface of the semiconductor device comprising an exposed surface of the semiconductive die and a first end of the TIV, laterally separated by the dielectric fill; and
coupling a thermal contact of a first material with a first external feature of the semiconductor device and an electrical contact of a second material with a second external feature.

17. The method of claim 16, further comprising:
removing the carrier substrate from the semiconductor device; and
coupling a heatsink to a second end of the TIV, opposite from the first end.

18. The method of claim 16, further comprising:
removing the carrier substrate from the semiconductor device; and
coupling a second semiconductive die comprising a second photonics region to a second end of the TIV, opposite from the first end.

19. The method of claim 16, wherein:
the first material exhibits a thermal conductivity of greater than about twenty watts per meter kelvin and an electrical resistivity of greater than about 10 billion ohm-cm.

20. The method of claim 19, wherein the first material is selected from the group consisting of Aluminum Nitride (AlN), Aluminum Oxide (Al2O3), Silicon Nitride (Si3N4), or Diamond.
